(19) United States
(12) Patent Application Publication
(10) Pub. No.: US 2011/0133185 A1
(43) Pub. Date: Jun. 9, 2011

(54) SEMICONDUCTOR DEVICE FORMATION SUBSTRATE AND SEMICONDUCTOR DEVICE MANUFACTURING METHOD

(75) Inventor: Shinji WAKISAKA, Hanno-shi (JP)

(73) Assignee: CASIO COMPUTER CO., LTD, Tokyo (JP)

(21) Appl. No.: 12/960,702

(22) Filed: Dec. 6, 2010

(30) Foreign Application Priority Data
Dec. 9, 2009 (JP) 2009-279060

(51) Int. Cl. H01L 23/58; H01L 21/66

(52) U.S. Cl. 257/48; 438/14; 257/E21.53; 257/E23.002

(57) ABSTRACT

A dummy columnar electrode having the same outer size and cross section as a columnar electrode formed in a semiconductor device formation region is formed in the peripheral part of a semiconductor device test region in the same process as the columnar electrode. The semiconductor device test regions are provided at several places on the peripheral edge of an effective semiconductor wafer region. Each of the semiconductor device test regions is formed to partly protrude out of the effective semiconductor wafer region. Thus, the number of the semiconductor device formation regions to be products can be prevented from decreasing.

### CROSS-REFERENCE TO RELATED APPLICATIONS

This application is based upon and claims the benefit of priority from prior Japanese Patent Application No. 2009-279060, filed Dec. 9, 2009, the entire contents of which are incorporated herein by reference.

### BACKGROUND OF THE INVENTION

1. Field of the Invention

The present invention relates to a semiconductor device and a manufacturing method of the same.

2. Description of the Related Art

A method of obtaining a semiconductor device is known from Jpn. Pat. Appln. KOKAI Publication No. 2005-93461. According to this method, columnar electrodes and a sealing film that fills a space between the columnar electrodes are formed on a semiconductor wafer in which a semiconductor integrated circuit is formed. These components are diced into an outer size equal to the size of a diced semiconductor chip. The semiconductor device formed by this method has the same size as the size of the semiconductor chip, and is therefore referred to as a chip size package (CSP). This semiconductor device is packaged in a semiconductor wafer state, and is otherwise referred to as a wafer level package (WLP).

The columnar electrode in the above-mentioned CSP is in the shape of a circular cylinder having a height of about 100 μm. A solder ball is mounted on the upper surface of the columnar electrode, and the columnar electrode is then joined to a connection terminal of a circuit board by a flip chip bonding (also referred to as face down bonding) method.

As the sealing film is formed on a semiconductor substrate around the columnar electrodes, an alignment mark provided on the semiconductor substrate cannot be seen after the sealing film is formed. Accordingly, another method may be used to form, together with the columnar electrodes, an alignment electrode as the alignment mark for mounting the solder ball on the columnar electrode and for laser-marking the rear surface of the semiconductor substrate.

In such a semiconductor device having high columnar electrodes, a high stress resulting from external impact or changes in surrounding environment acts on the columnar electrodes connected to the connection terminal of the circuit board. Thus, after the columnar electrodes are formed, columnar electrodes at several places have to be put to a strength test such as a shear test to check whether these columnar electrodes satisfy a specified value. This strength test is a breakdown test. The disadvantage is that the semiconductor devices having the columnar electrodes which have undergone the strength test cannot serve as products.

According to the present invention, a semiconductor device test region partly protrudes from an effective semiconductor wafer region of a semiconductor device formation substrate. Thus, the number of semiconductor device formation regions to be products can be prevented from decreasing.

### BRIEF SUMMARY OF THE INVENTION

According to one aspect of the present invention, there is provided a semiconductor device formation substrate comprising: a semiconductor device formation region (11, 51) including columnar electrodes (21) connected to an integrated circuit; and a semiconductor device test region (11a, 51a) for a strength test in which dummy columnar electrodes (21b) are formed and which includes a portion that protrudes out of an effective semiconductor wafer region (1a).

According to another aspect of the present invention, there is provided a semiconductor device manufacturing method comprising: forming, on a device region including an integrated circuit and disposed in a semiconductor substrate (31), a semiconductor device formation region (11, 51) including columnar electrodes (21) connected to the integrated circuit; and forming a semiconductor device test region (11a, 51a) for a strength test including dummy columnar electrodes (21b) so that a portion of the semiconductor device test region (11a, 51a) protrudes out of an effective semiconductor wafer region (1a).

### BRIEF DESCRIPTION OF THE SEVERAL VIEWS OF THE DRAWINGS

FIG. 1 is a plan view of Embodiment 1 as one example of a semiconductor device formation substrate according to the present invention, and shows a mask for indicating the positions of semiconductor device test regions;

FIG. 2 is an enlarged plan view of a mask in a shot design drawing showing details within a region A that includes the semiconductor device test regions of FIG. 1;

FIG. 3 is an enlarged plan view showing details of an actual shot in the region A that includes the semiconductor device test regions of FIG. 1;

FIG. 4 is an enlarged sectional view cut along the line IV-IV of FIG. 2;

FIG. 5 is an enlarged sectional view for illustrating a first step regarding a manufacturing method of Embodiment 1;

FIG. 6 is an enlarged sectional view for illustrating a step following FIG. 5;

FIG. 7 is an enlarged sectional view for illustrating a step following FIG. 6;

FIG. 8 is an enlarged sectional view for illustrating a step following FIG. 7;

FIG. 9 is an enlarged sectional view for illustrating a step following FIG. 8;

FIG. 10 is an enlarged sectional view for illustrating a step following FIG. 9;

FIG. 11 is an enlarged sectional view for illustrating a step following FIG. 10;

FIG. 12 is an enlarged sectional view for illustrating a step following FIG. 11;

FIG. 13 is an enlarged sectional view for illustrating a step following FIG. 12;

FIG. 14 is an enlarged sectional view for illustrating a step following FIG. 13;

FIG. 15 is an enlarged plan view for illustrating a method of a shear test in the semiconductor device test region shown in FIG. 2;

FIG. 16 is a plan view of Embodiment 2 of the semiconductor device formation substrate according to this invention, and shows a mask for indicating the positions of semiconductor device test regions;

FIG. 17 is an enlarged plan view of a mask in a shot design drawing showing details within a region B that includes the semiconductor device test regions of FIG. 16;

FIG. 18 is an enlarged plan view for illustrating a method of a shear test in the semiconductor device test region shown in FIG. 17; and

FIG. 19 is an enlarged sectional view showing a modification of the semiconductor device formation substrate according to the present invention.

### DETAILED DESCRIPTION OF THE INVENTION

### Embodiment 1

A method of manufacturing a semiconductor device formation substrate and a semiconductor device according to this invention will hereinafter be described.

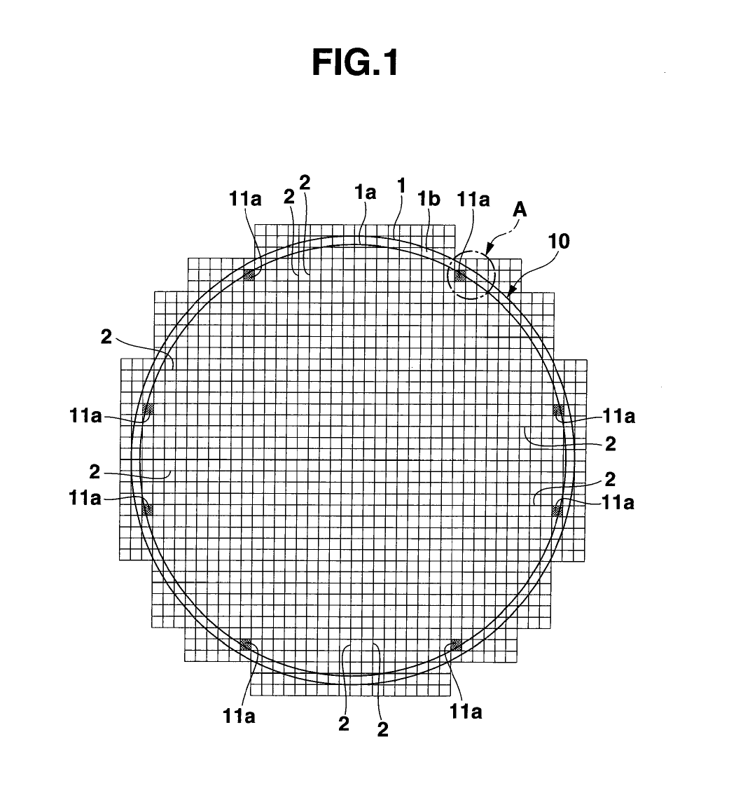

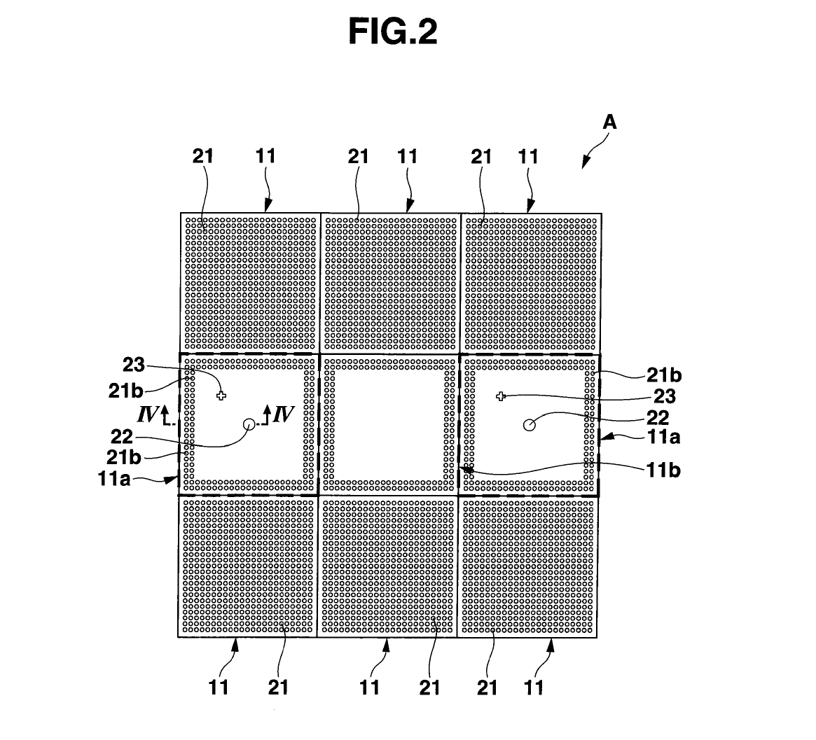

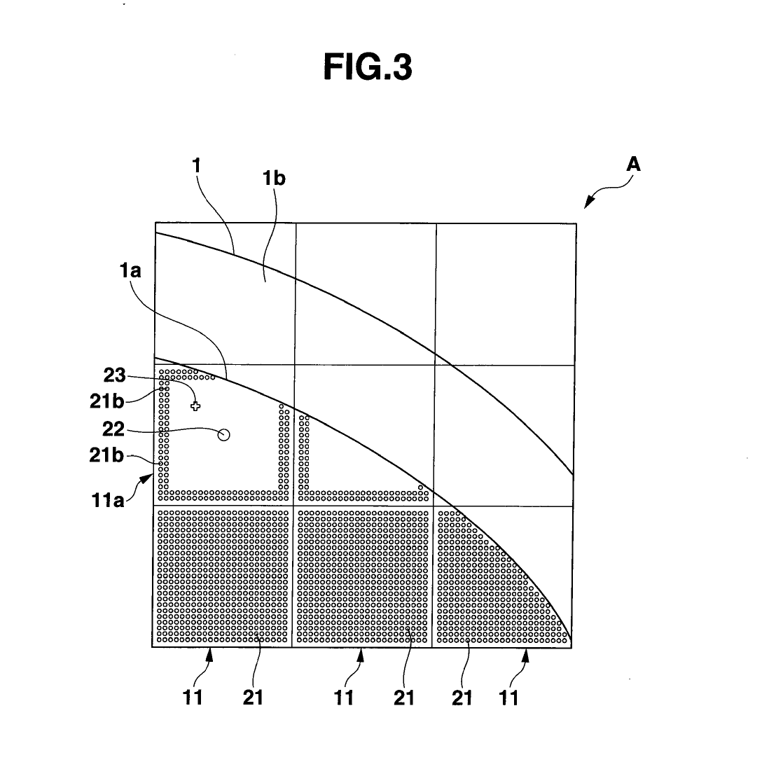

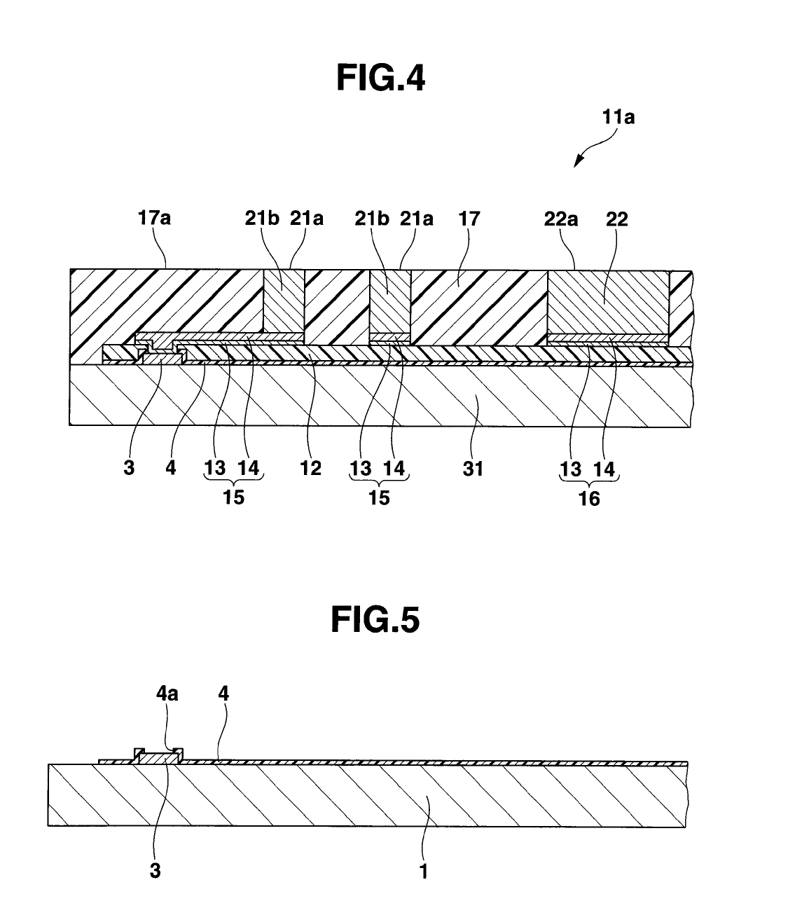

FIG. 1 is a mask diagram (plan view) of a semiconductor device formation substrate 10 according to Embodiment 1 of this invention. FIG. 2 is a mask diagram (enlarged plan view) of a shot design drawing showing details of a region A indicated by a dotted circular mark in FIG. 1. FIG. 3 is a view of a semiconductor device test region 11a when the mask diagram of the shot design drawing in FIG. 2 is actually shot in the region A shown in FIG. 1. FIG. 4 is an enlarged sectional view cut along the line IV-IV of FIG. 2.

In FIG. 1, a reference number 1 denotes a semiconductor wafer comprising, for example, a silicon substrate, and a reference number 1a denotes an effective semiconductor wafer region of the semiconductor wafer 1. In general, the effective semiconductor wafer region 1a is smaller about 3 to 5 mm in radius than the semiconductor wafer 1 due to a removed grip margin. The effective semiconductor wafer region 1a has a plurality of semiconductor device formation regions 11 that are separated by dicing lines 2 formed in row and column directions. An integrated circuit (not shown) is formed on the main surface of each of the semiconductor device formation regions 11. Although described later, a columnar electrode formed on the integrated circuit is formed in each of the semiconductor device formation regions 11. Nothing is formed in an invalid semiconductor wafer region 1b located outside of the effective semiconductor wafer region 1a. The semiconductor device formation regions 11 are created from the semiconductor wafer 1 by being exposed stepwise so that 3×3 semiconductor device formation regions surrounded by a thick solid square frame are treated as one unit. In the region A indicated by the dotted circular mark in FIG. 1, a region in which a plurality of slant lines are drawn to cross one another is the semiconductor device test region 11a to undergo a later-described strength test. The semiconductor device test regions 11a are arranged at eight places on the peripheral edge of the semiconductor device formation substrate 10. The semiconductor device formation substrate 10 is in the same shape as the semiconductor wafer 1 when viewed from above.

Each of the semiconductor device test regions 11a is formed to partly protrude out of the effective semiconductor wafer region 1a.

FIG. 2 is an enlarged plan view showing details of the semiconductor device formation regions 11 and the semiconductor device test regions 11a in the region A shown in FIG. 1. FIG. 3 is a view of the semiconductor device test region 11a when the mask diagram in FIG. 2 is shot in the region A shown in FIG. 1. The region A has 3×3 small regions equal in outer size and cross section. A plurality of columnar electrodes 21 equal in outer size and cross section are only arranged in matrix form in a total of six semiconductor device formation regions 11 that are arranged in the upper and lower rows. The semiconductor device test regions 11a for the strength test are disposed on the left and right sides of the middle row. A semiconductor device test region 11b is disposed in the center of the middle row. Dummy columnar electrodes 21b are formed in the peripheral part of each of the semiconductor device test regions 11a. In the central region of each of the semiconductor device test regions 11a, a false alignment electrode 22 and a true alignment electrode 23 are formed. The semiconductor device test region 11b disposed in the center of the middle row has an external connection electrode arrangement portion in which the dummy columnar electrodes 21b are arranged in the peripheral part. In the central region, the semiconductor device test region 11b has an electrode non-formation portion where no electrodes such as the dummy columnar electrode 21b and the alignment electrodes 22 and 23 are formed. The electrode non-formation portion is formed over a region greater than the number of rows of the dummy columnar electrodes formed in a dummy columnar electrode arrangement portion. The area of the electrode non-formation portion is greater than the area of the dummy columnar electrode arrangement portion.

The columnar electrodes 21 in the semiconductor device formation region 11 adjacent to the semiconductor device test regions 11a and 11b have a problem of overgrowing due to excessive passage of a current during plating growth if the dummy columnar electrodes 21b are not present in the semiconductor device test regions 11a and 11b. In order to lessen such abnormal growth, the dummy columnar electrodes 21b are provided in the semiconductor device test regions 11a and 11b so that the current also runs through the dummy columnar electrodes 21b and the concentration of the current can be relieved.

Furthermore, the dummy columnar electrodes 21b in the semiconductor device test regions 11a and 11b are physically connected to the integrated circuit, but do not operate. As the dummy columnar electrodes 21b are not present in the effective semiconductor wafer region 1a, some wiring lines are broken. Therefore, there is no problem even if the dummy columnar electrodes 21b in the semiconductor device test regions 11a and 11b are not connected in the integrated circuit.

Among 3×3 small regions in the region A shown in FIG. 3, regions having all the columnar electrodes 21 located in the effective semiconductor wafer region 1a are actually usable as a semiconductor device. Thus, two semiconductor device formation regions 11 are only usable.

In regions other than the eight regions A including the semiconductor device test regions 11a shown in FIG. 1, all of the 3×3 regions are the semiconductor device formation regions 11, and there is no electrode non-formation portion. Although the regions A are provided at eight places, the regions A may be provided at any even number of places ranging from 4 to 10 places.

The alignment electrodes are necessary for a dicing process called a post-process and for positioning to mount a solder ball. The false alignment electrode 22 formed in the semiconductor device test region 11a functions as a mark for rough alignment using an alignment lens having low magnifying power. The false alignment electrode 22 is greater in outer size than the dummy columnar electrode 21b. The true alignment electrode 23 functions as a mark for accurate alignment using a lens having high magnifying power after the rough alignment using the false alignment electrode 22. The true alignment electrode 23 is greater in outer size than the dummy columnar electrode 21b and smaller in outer size than the false alignment electrode 22.

By way of example, the outer size of each of the semiconductor device formation region 11 and the semiconductor device test regions 11a and 11b is about 7.5 mm². The outer size of the false alignment electrode 22 is about 1 mmΦ. The true alignment electrode 23 has an outer size of a combination of crossed straight line portions having a length of about 0.5 mm and a width of about 0.15 mm.

FIG. 4 is an enlarged sectional view, cut along the line IV-IV, of the semiconductor device test region 11a disposed in the region A shown in FIG. 2.

The semiconductor device test region 11a includes a semiconductor substrate 31 having the integrated circuit (not shown) formed on the main surface (upper surface) side. On the integrated circuit, the semiconductor device test region 11a has a plurality of connection pads 3 connected to the integrated circuit are provided. Here, the semiconductor substrate 31 is a part that corresponds to the semiconductor device test regions 11a of the semiconductor wafer 1 shown in FIG. 1. The connection pad 3 is made of, for example, an aluminum-based metal. A first insulating film 4 having an opening that exposes the center of the connection pad 3 is formed on the main surface of the semiconductor substrate 31. The first insulating film 4 is made of an inorganic material such as silicon oxide or silicon nitride. The peripheral side surface of the first insulating film 4 stands back from the side surface of the semiconductor substrate 31.

A second insulating film 12 is formed on the first insulating film 4. The second insulating film 12 is made of an organic resin material such as a polyimide resin or poly-p-phenylene-benzobisoxazole (PBO). An opening that exposes the center of the connection pad 3 is also formed in the second insulating film 12. The peripheral side surface of the second insulating film 12 is located at the same position as the peripheral side surface of the first insulating film 4, and stands back from the side surface of the semiconductor substrate 31.

A wiring line 15 having one end connected to the connection pad 3 via the opening of the second insulating film 12 is formed on the second insulating film 12. The wiring line 15 has a double layer structure including a first wiring line 13 and a second wiring line 14 formed on the first wiring line 13. The first wiring line 13 and the second wiring line 14 can be made of a copper-based metal. The wiring line 15 is not limited to the double layer structure, and can have a laminated structure having three or more layers. In this case, one or more metal layers made of, for example, titanium (Ti), tungsten (W) or an alloy of titanium and tungsten intervene.

The wiring line 15 shown in the center of FIG. 4 is connected to the unshown connection pad 3. In FIG. 4, a pad 16 in which the first wiring line 13 and the second wiring line 14 are stacked is formed in a right part on the second insulating film 12. The pad 16 is not connected to the integrated circuit, and is electrically isolated from the surrounding wiring line 15.

The other end of each wiring line 15 serves as a land, and the dummy columnar electrode 21b is formed on the land. The dummy columnar electrode 21b has a flat upper surface 21a, and is in the shape of, for example, a circular cylinder having a diameter of 40 to 100 μm and a height of 40 to 80 μm. The dummy columnar electrode 21b is made of, for example, a copper-based metal. The false alignment electrode 22 is formed on the pad 16. Although not shown in FIG. 4, the true alignment electrode 23 is also similar in structure to the false alignment electrode 22. The true alignment electrode 23 is not connected to the integrated circuit, and is provided on the pad electrically isolated from the surrounding wiring line 15.

A sealing film 17 made of a polyimide resin or epoxy resin is formed on the second insulating film 12 in regions around the dummy columnar electrode 21b, the false alignment electrode 22 and the true alignment electrode 23. The sealing film 17 covers the wiring line 15 of the dummy columnar electrode 21b. Furthermore, the sealing film 17 is formed on the semiconductor substrate 31 around the first insulating film 4 and the second insulating film 12, and covers the peripheral side surface of the first insulating film 4 and the peripheral side surface of the second insulating film 12.

An upper surface 17a of the sealing film 17 is flush with or slightly higher than the upper surface 21a of the dummy columnar electrode 21b, an upper surface 22a of the false alignment electrode 22 and the upper surface of the true alignment electrode 23.

The semiconductor device test region 11b is similar in structure to the semiconductor device test region 11a shown in FIG. 4. However, the false alignment electrode 22 and the true alignment electrode 23 are not formed in the semiconductor device test region 11b. The space on the second insulating film 12 in this region is filled with the sealing film 17.

Furthermore, in each of the semiconductor device formation regions 11 shown in FIG. 2, the columnar electrodes 21 similar in shape to the dummy columnar electrode 21b shown in the semiconductor device test regions 11a are arranged in matrix form in the entire region on the second insulating film 12, if explained with reference to the semiconductor device test region 11a shown in FIG. 4.

Now, an example of a method of manufacturing the semiconductor device formation substrate 10 shown in FIG. 1 is described with reference to FIG. 5 to FIG. 14. In the semiconductor device formation region 11 and the semiconductor device test regions 11a and 11b, the processes of forming the columnar electrode 21 and the dummy columnar electrode 21b are exactly the same, and the outer size and cross section of the columnar electrode 21 and the dummy columnar electrode 21b in the regions 11a and 11b are also the same. Thus, although the semiconductor device test region 11a is illustrated in the drawings, parts associated with the formation of the dummy columnar electrode 21b represent the entire manufacturing method.

First, as shown in FIG. 5, a semiconductor wafer 1 is prepared. The semiconductor wafer 1 has an integrated circuit (not shown) and a connection pad 3 connected to the integrated circuit on the main surface side in each device region (corresponding to each semiconductor device formation region 11 or semiconductor device test region 11a, 11b). A first insulating film 4 is then formed in each device region of the semiconductor wafer 1. The first insulating film 4 has an opening 4a that exposes the center of the connection pad 3, and covers the main surface of the semiconductor wafer 1. The connection pad 3 is made of, for example, an aluminum-based metal. In order to form the first insulating film 4, an inorganic material such as silicon oxide or silicon nitride is formed into a film on the entire surface of the semiconductor wafer 1 by a chemical vapor deposition (CVD) method, and the first opening 4a is made in this inorganic material film, and then the film is patterned so that its peripheral side surface may be positioned to stand back from the side surface of the semiconductor wafer 1. A generally known photolithographic technique is used for the patterning of the inorganic material film. In short, a photoresist is formed into a film on the inorganic material film and patterned by exposure and development, and the patterned photoresist is used as a mask to etch the inorganic material film. The etching may be wet etching or dry etching. Hereinafter, such a technique is simply referred to as a photolithographic technique and is not described.

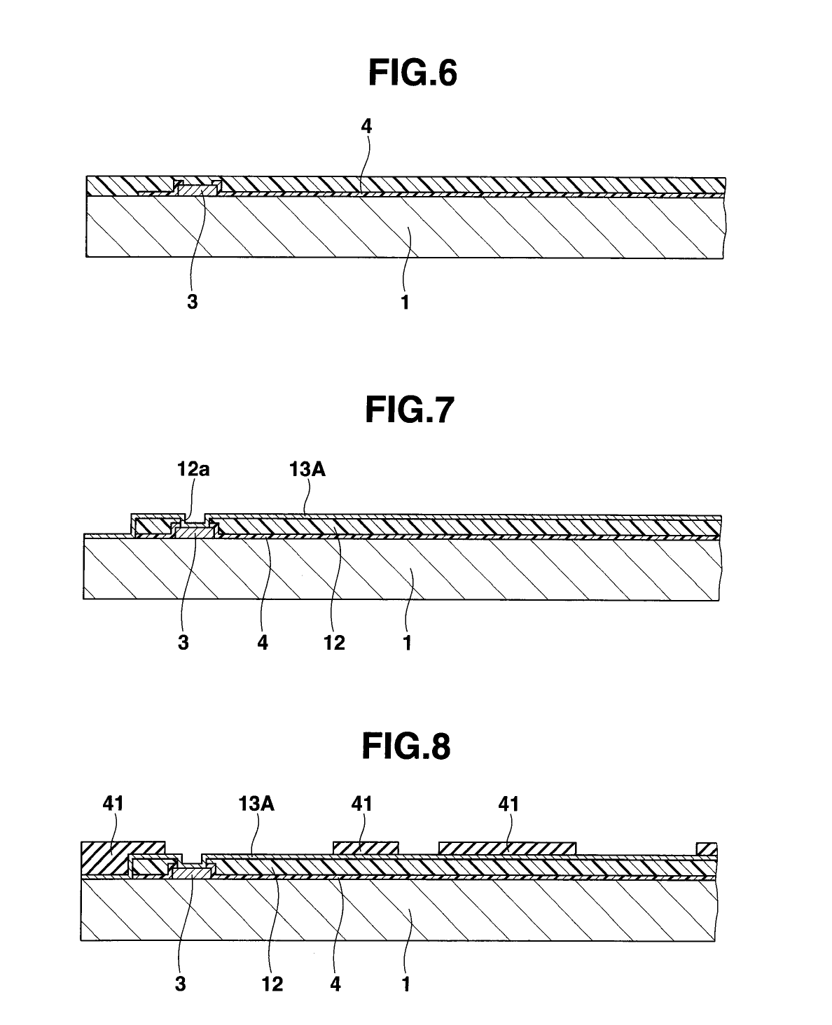

Furthermore, as shown in FIG. 6, an organic resin such as a polyimide resin or PBO resin is solidly applied to the first insulating film 4, the connection pad 3 and the semiconductor wafer 1 around the first insulating film 4. A proper method can be used as an application method, such as a spin coating method, screen printing method or scan coating method.

An opening 12a that exposes the center of the connection pad 3 is formed in the solidly applied organic resin film by the photolithographic technique. At the same time, the periphery of the second insulating film 12 is removed so that the position of the peripheral side surface of the second insulating film 12 may coincide with the position of the peripheral side surface of the first insulating film 4.

A metal film 13A made of, for example, a copper-based metal is then formed by a sputtering or electroless plating method on the entire upper surface of the second insulating film 12, on the connection pad 3 exposed through the opening 12a of the second insulating film 12, and on the semiconductor wafer 1 around the second insulating film 12. Although described later, the metal film 13A is patterned into a first wiring line 13. This condition is shown in FIG. 7.

A photoresist 41 is applied to the entire upper surface of the metal film 13A, and patterned by the photolithographic technique into a shape having an opening corresponding to a second wiring line 14. The shape of the opening corresponding to the second wiring line 14 in this case includes a shape corresponding to a pad 16. This condition is shown in FIG. 8.

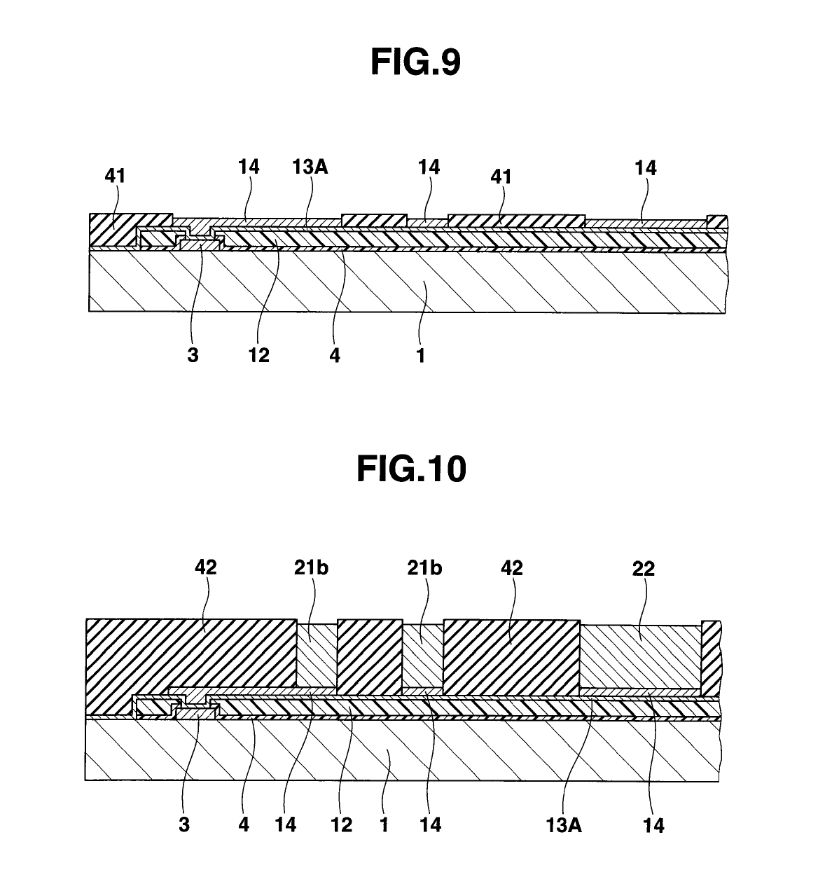

Electrolytic plating is then carried out, and the metal film 13A is used as a current path to form the second wiring line 14 on the metal film 13A exposed through each opening. This condition is shown in FIG. 9. Subsequently, the photoresist film 41 is detached.

A photoresist film 42 is then solidly applied to the metal film 13A and the second wiring line 14. This photoresist 42 is formed so that its upper surface may be positioned higher than a dummy columnar electrode 21b, a false alignment electrode 22 and a true alignment electrode 23 that will be formed later. The photoresist film 42 is then patterned by the photolithographic technique to have openings in the shapes of the dummy columnar electrode 21b, the false alignment electrode 22 and the true alignment electrode 23 that are to be formed. Further, the metal film 13A is used as a current path to carry out electrolytic plating, so that the dummy columnar electrode 21b, the false alignment electrode 22 and the true alignment electrode 23 are formed on the second wiring line 14 exposed through each opening of the photoresist film 42. This condition is shown in FIG. 10. However, the true alignment electrode 23 is not shown in FIG. 10.

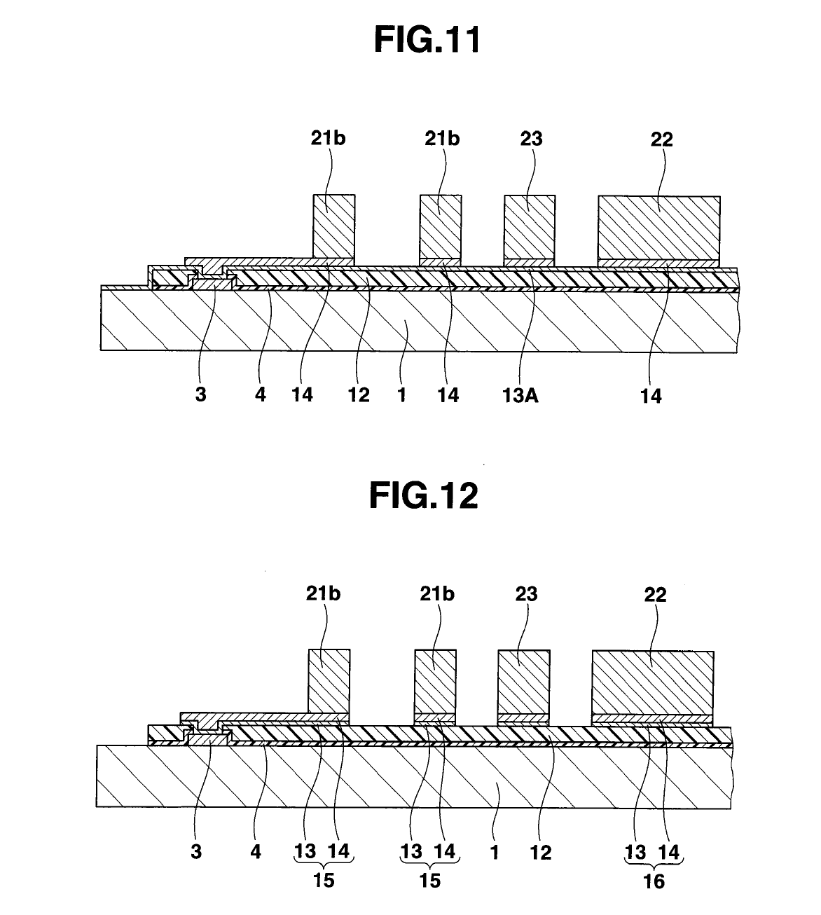

Furthermore, the photoresist film 42 is detached, so that the metal film 13A located under the photoresist film 42 is exposed as shown in FIG. 11. The second wiring line 14 is then used as a mask to etch the metal film 13A. As a result, the first wiring line 13 having the same pattern as the second wiring line 14 is formed. That is, the second wiring line 14 is stacked on the first wiring line 13, so that a wiring line 15 connected to the integrated circuit is formed. The pad 16 which is not connected to the integrated circuit and which is electrically isolated from the wiring line 15 is also formed. This condition is shown in FIG. 12.

In the condition shown in FIG. 12, a shear test of the dummy columnar electrode 21b is conducted. The shear test is conducted on the dummy columnar electrode 21b formed in the semiconductor device test region 11a. Referring to FIG. 1, each of the semiconductor device test regions 11a arranged at eight places in the semiconductor device formation substrate 10 partly protrudes out of the effective semiconductor wafer region 1a. That is, one of the right and left semiconductor device test regions 11a (regions indicated by thick dotted square frame in FIG. 2) arranged in the region A in FIG. 2 is mostly formed in the effective semiconductor wafer region 1a, and only a small portion of this region protrudes out of the effective semiconductor wafer region 1a.

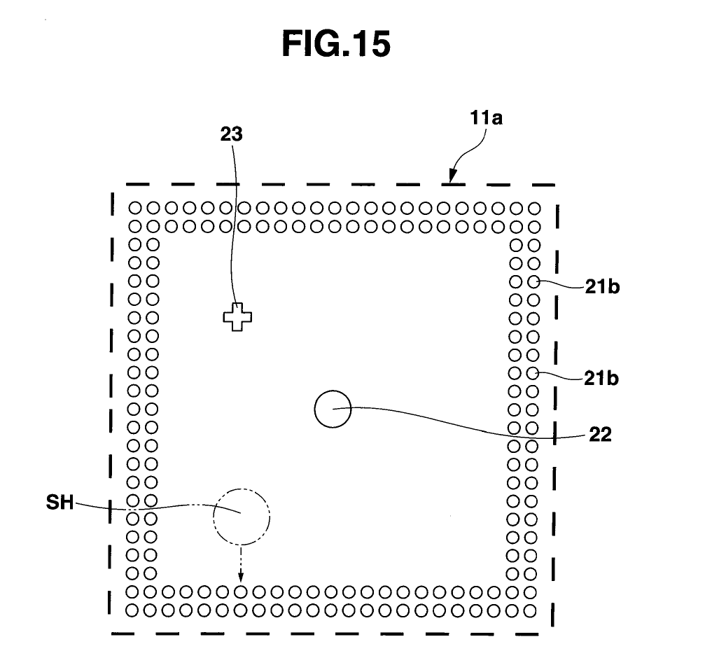

The shear test is conducted on the dummy columnar electrode 21b formed in such a semiconductor device test region 11a. As shown in FIG. 15, a head SH of a shear tester indicated by a chain double-dashed line circular mark is dropped between the dummy columnar electrode 21b disposed in the peripheral part of the semiconductor device test region 11a and the false alignment electrode 22 or the true alignment electrode 23 formed in the central region. The head SH is applied to any one of the dummy columnar electrodes 21b to put pressure on this electrode in a direction indicated by a dashed-dotted line arrow, thereby measuring the shear strength of the dummy columnar electrode 21b. The head SH can be replaced in accordance with the diameter of the dummy columnar electrode 21b and the distance between the dummy columnar electrodes 21b so that the head SH may not collide with the dummy columnar electrodes 21b on both sides of the dummy columnar electrode 21b to be measured. After one dummy columnar electrode 21b is measured, the head SH of the shear tester is moved to measure another dummy columnar electrode 21b. After several (about 3 to 7) dummy columnar electrodes 21b are measured in one semiconductor device test region 11a, a similar shear test is conducted in another semiconductor device test region 11a. This operation is repeated. In the example of the semiconductor device formation substrate 10 shown in FIG. 1, shear tests can be conducted on the semiconductor device test regions 11a at eight places.

The shear test according to the present invention is conducted using the regions that cannot serve as products. Thus, the regions to be products are not reduced. That is, according to the present invention, the number of the semiconductor device formation regions 11 to be products can be prevented from decreasing.

However, in order to conduct the shear test with accuracy, the shear test has to be conducted on the dummy columnar electrode 21b which is formed under a manufacturing condition substantially equal to that of a manufactured product. Therefore, the area of the region of the semiconductor device test region 11a that protrudes out of the effective semiconductor wafer region 1a has to be about 20% or less of the area of the whole region. In this case, not all of the semiconductor device test regions 11a formed in the semiconductor device formation substrate 10 fulfill the above-mentioned condition. The shear test has only to be conducted on the semiconductor device test regions 11a that satisfy the condition. When the first wiring line 13 is significantly thin and there is substantially no influence of the etching of the first wiring line 13 on the shear test, the shear test can be conducted in the condition shown in FIG. 11 before the metal film 13A is patterned.

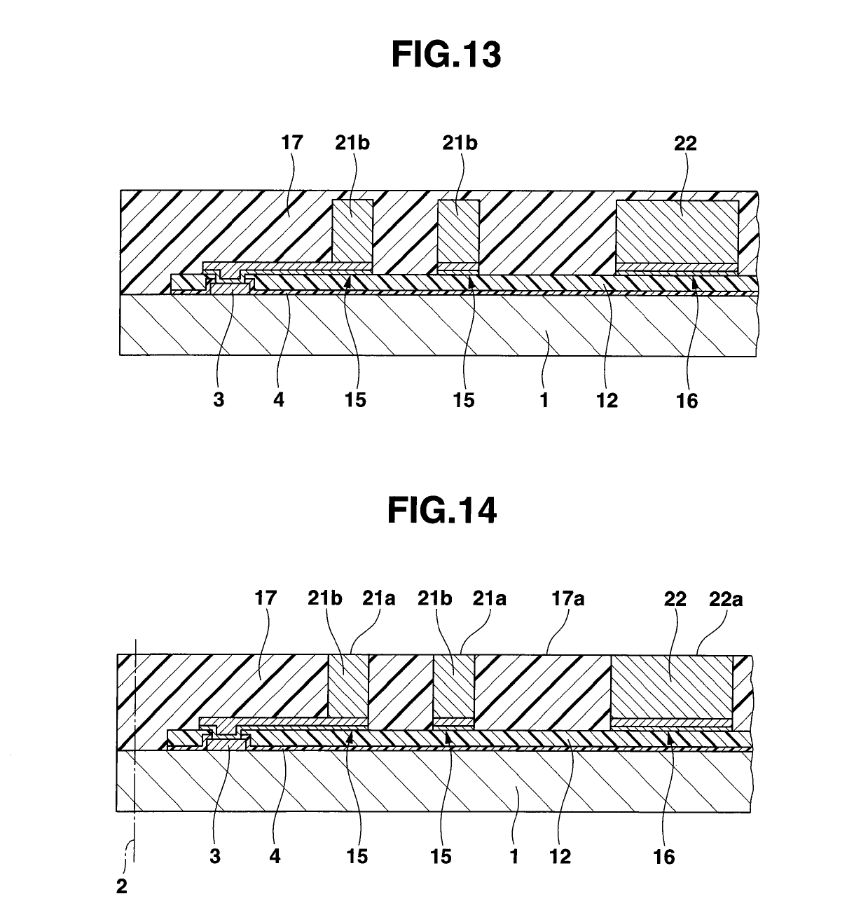

The following process is performed after the shear test is conducted. However, the following process is only performed when the semiconductor device test region 11a has passed the shear test, and does not have to be performed when the semiconductor device test region 11a has not passed the shear test. After the shear test is conducted, a sealing film 17 is first formed. As shown in FIG. 13, the sealing film 17 is formed on the second insulating film 12 to be thick enough to cover the upper surfaces of the dummy columnar electrode 21b, the false alignment electrode 22 and the true alignment electrode 23.

Furthermore, the upper part of the sealing film 17 is ground as shown in FIG. 14 to expose the upper surface 21a of the dummy columnar electrode 21b, the upper surface 22a of the false alignment electrode 22 and the upper surface of the true alignment electrode 23.

As the dummy columnar electrode 21b, the false alignment electrode 22 and the true alignment electrode 23 are formed by electrolytic plating, the dummy columnar electrodes 21b are different in height from one another. Moreover, the upper surface 21a of the dummy columnar electrode 21b, the upper surface 22a of the false alignment electrode 22 and the upper surface of the true alignment electrode 23 are considerably uneven. Thus, in the step of exposing the upper surface 21a of the dummy columnar electrode 21b, the upper surface 22a of the false alignment electrode 22 and the upper surface of the true alignment electrode 23, the upper sides of the dummy columnar electrode 21b, the false alignment electrode 22 and the true alignment electrode 23 are ground together with the sealing film 17. The dummy columnar electrode 21b, the false alignment electrode 22 and the true alignment electrode 23 are made of a soft metal such as a copper-based metal. Therefore, although not shown in FIG. 14, shear drops are formed in the upper surfaces of the electrodes 21b, 22 and 23 in the step of grinding the upper surfaces of the electrodes 21b, 22 and 23. If solder balls are mounted on these shear-drop-containing upper surfaces of the electrodes 21b, 22 and 23 and subjected to reflow processing, the solder balls are deformed, so that sufficient bonding strength cannot be obtained when the solder balls are soldered to external terminals.

Thus, the upper surface 21a of the dummy columnar electrode 21b, the upper surface 22a of the false alignment electrode 22 and the upper surface of the true alignment electrode 23 may be etched to remove the upper surfaces of the electrodes 21, 22 and 23 together with the shear drops. After this process is performed, the upper surface 21a of the dummy columnar electrode 21b, the upper surface 22a of the false alignment electrode 22 and the upper surface of the true alignment electrode 23 are slightly lower than the upper surface 17a of the sealing film 17.

Furthermore, a solder ball is formed on the upper surface of the columnar electrode 21 in the semiconductor device formation region 11. In this process, a solder ball is mounted on the upper surface 21a of the columnar electrode 21 in the semiconductor device formation region 11, and the semiconductor device formation substrate 10 is brought into a reflow furnace and subjected to reflow processing. As a result of this reflow processing, the solder ball is joined to the upper surface 21a of the columnar electrode 21.

The false alignment electrode 22 and the true alignment electrode 23 are used to align the solder ball with the columnar electrode 21. The solder balls do not have to be formed on the dummy columnar electrodes 21b in the semiconductor device test regions 11a and 11b.

However, the solder balls may be formed on the dummy columnar electrodes 21b in the semiconductor device test regions 11a and 11b if efficiency is provided in terms of the process.

In FIG. 14, no solder ball is formed on the dummy columnar electrode 21b in the semiconductor device test region 11a.

Furthermore, a mark is put on the rear surface of the semiconductor wafer 1 if necessary. The false alignment electrode 22 and the true alignment electrode 23 can also be used for the alignment in this process.

The sealing film 17 and the semiconductor wafer 1 are then cut along a dicing line 2 indicated by a chain double-dashed line in FIG. 14. Thus, a plurality of semiconductor devices can be obtained at the same time.

In the semiconductor device formation substrate 10 according to Embodiment 1, the semiconductor device test region 11a including the dummy columnar electrodes 21b to undergo the shear test partly protrudes out of the semiconductor device formation substrate 10. Thus, the number of the semiconductor device formation regions to be products can be prevented from decreasing. Moreover, the dummy columnar electrode 21b for the shear test, the false alignment electrode 22 and the true alignment electrode 23 are formed in the same semiconductor device test region 11a. Thus, the regions for only forming the alignment electrodes in the semiconductor device formation substrate 10 can serve as regions for product formation, and the semiconductor device formation regions to be products can be increased.

As shown in FIG. 15, the semiconductor device test region 11a has a greater space formed in the central region than in the peripheral part where the dummy columnar electrodes 21b are arranged. Therefore, advantageously, the operation of dropping the head SH of the shear tester is facilitated, and the shear test can be efficiently conducted.

### Embodiment 2

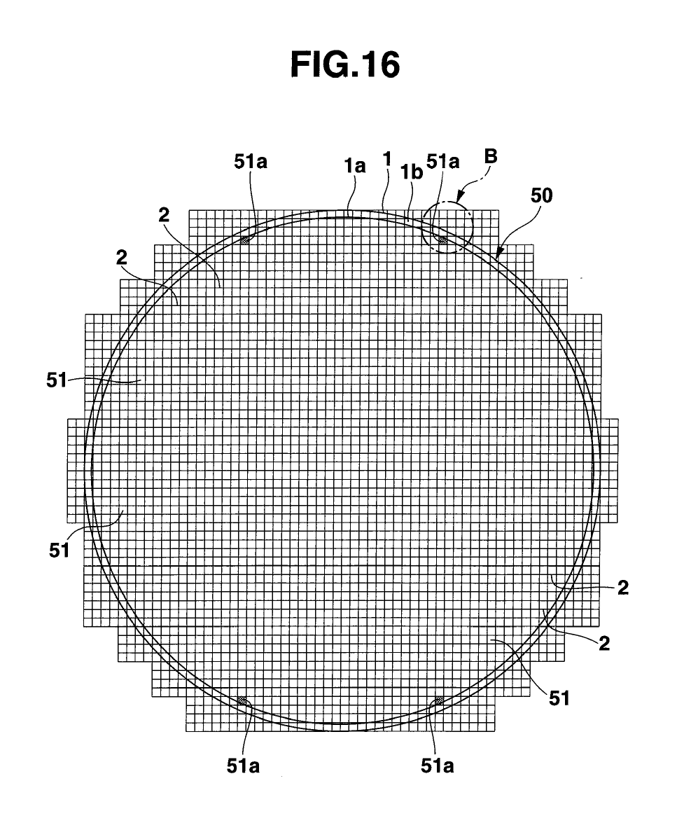

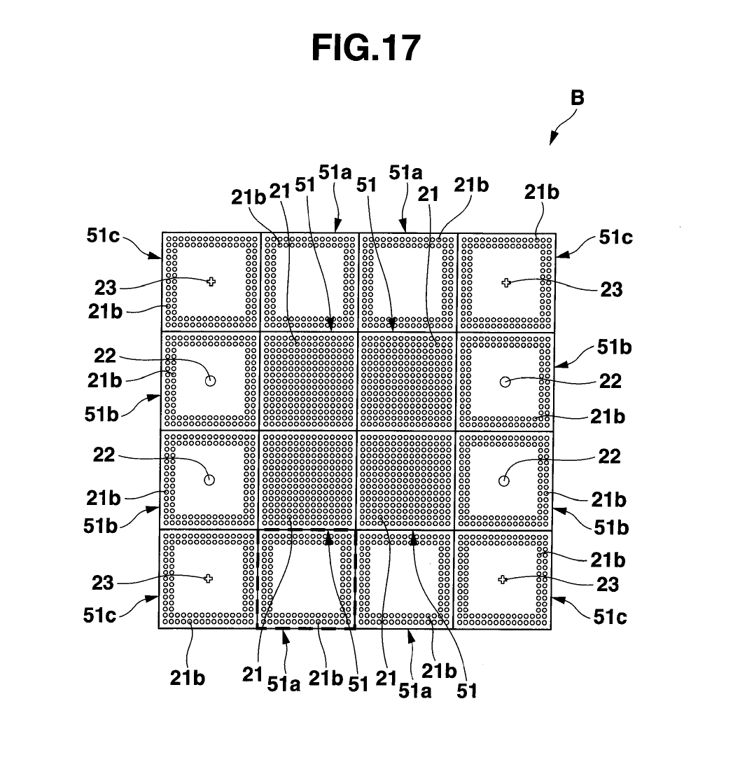

FIG. 16 is a mask diagram (plan view) of a semiconductor device formation substrate 50 according to Embodiment 2 of this invention. FIG. 17 is a mask diagram (enlarged plan view) of a shot design drawing showing details of a region B indicated by a dotted circular mark in FIG. 16.

In the semiconductor device formation substrate 50 shown in FIG. 16, semiconductor device formation regions 51 are formed by being exposed stepwise so that 4×4 semiconductor device formation regions 51 surrounded by a thick solid square frame are treated as one unit. The semiconductor device formation substrate 50 is in the same shape as the semiconductor wafer 1 when viewed from above.

As shown in FIG. 17, four kinds of small regions are provided in the region B. The first kind is the semiconductor device formation region 51 in which columnar electrodes 21 alone are arranged in matrix form. The second kind is a first semiconductor device test region 51a. The first semiconductor device test region 51a has a dummy columnar electrode arrangement portion in which dummy columnar electrodes 21b alone are arranged in the peripheral part. No electrodes are formed in the central region inside the dummy columnar electrode arrangement portion. The third kind is a second semiconductor device test region 51b. The second semiconductor device test region 51b has a dummy columnar electrode arrangement portion in which dummy columnar electrodes 21b alone are arranged in the peripheral part. A false alignment electrode 22 is formed substantially in the center of the second semiconductor device test region 51b. The fourth kind is a third semiconductor device test region 51c. The third semiconductor device test region 51c has a dummy columnar electrode arrangement portion in which dummy columnar electrodes 21b alone are arranged in the peripheral part. A true alignment electrode 23 is formed substantially in the center of the third semiconductor device test region 51c. For each of the regions 51, 51a, 51b and 51c, the number of regions is four. These regions are arranged at positions shown in FIG. 17.

Referring to FIG. 16, the first semiconductor device test regions 51a in which a plurality of slant lines are drawn to cross one another are arranged at four places in the semiconductor device formation substrate 50. At any of the four places, the first semiconductor device test region 51a partly protrudes out of an effective semiconductor wafer region 1a.

The position of each of the first semiconductor device test regions 51a at four places shown in FIG. 16 corresponds to the position of the first semiconductor device test region 51a which is the second from the left in the lowermost row in FIG. 17 and which is surrounded by a thick dotted square frame.

In the semiconductor device formation substrate 50 shown in FIG. 16, a shear test is conducted on the dummy columnar electrode 21b formed in the first semiconductor device test region 51a.

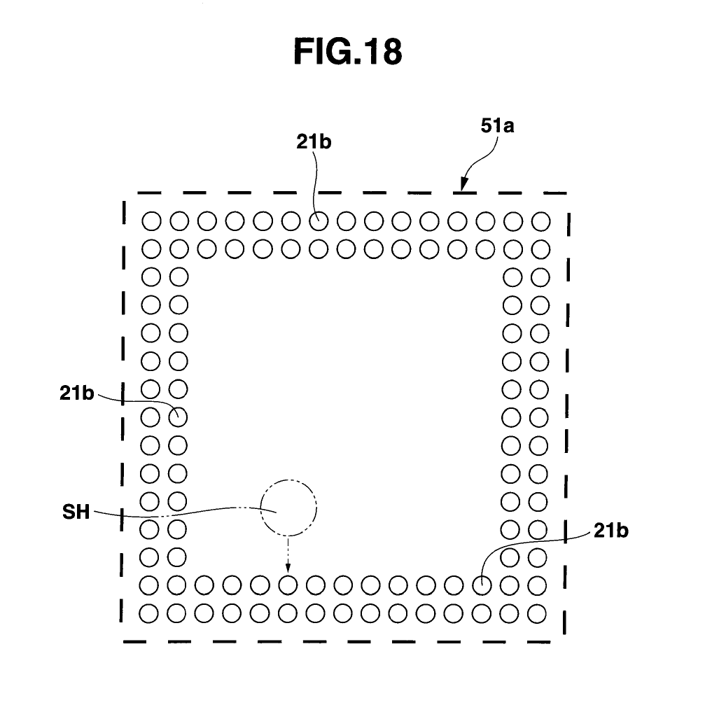

As shown in FIG. 18, a head SH of a shear tester indicated by a chain double-dashed line circular mark is dropped at a position closer to the center than the columnar electrode arrangement portion in the peripheral part of the first semiconductor device test region 51a where the dummy columnar electrodes 21b are arranged. The head SH is applied to any one of the dummy columnar electrodes 21b to put pressure on this electrode in a direction indicated by a dashed-dotted line arrow, thereby measuring the shear strength of the dummy columnar electrode 21b. After one dummy columnar electrode 21b is measured, the head SH of the shear tester is moved to measure the shear strength of another dummy columnar electrode 21b. After several (about 3 to 7) dummy columnar electrodes 21b are measured in one first semiconductor device test region 51a, a similar shear test is conducted in another first semiconductor device test region 51a. This operation is repeated in the first semiconductor device test regions 51a at four places.

According to Embodiment 2, the first semiconductor device test regions 51a including the dummy columnar electrodes 21b to undergo the shear test partly protrudes out of the semiconductor device formation substrate 50. Thus, the number of the semiconductor device formation regions to be products can be prevented from decreasing.

(Modification)

In the structures according to the embodiments described above, the false alignment electrode 22 and the true alignment electrode 23 are formed on the second wiring line 14 similarly to the dummy columnar electrodes 21b. However, the false alignment electrode 22 and the true alignment electrode 23 may be different in structure from the dummy columnar electrodes 21b.

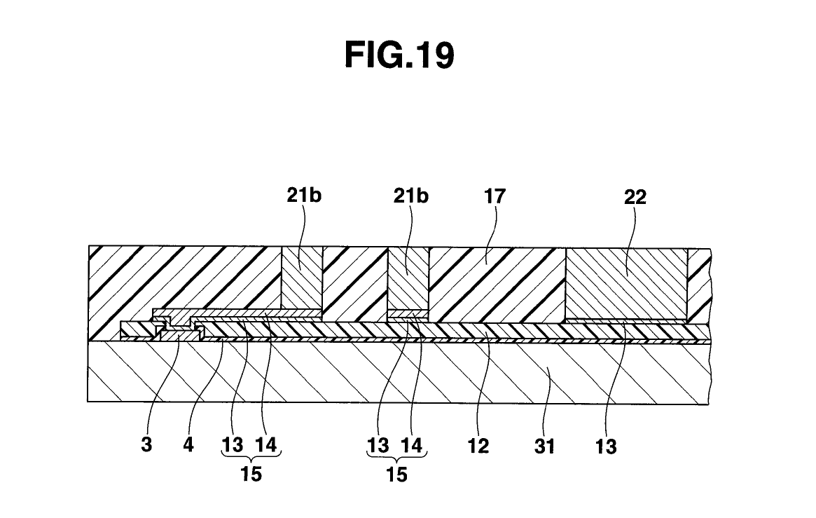

FIG. 19 is an enlarged sectional view showing a modification of the semiconductor device test region according to the present invention. In this modification, the false alignment electrode 22 is directly formed on the first wiring line 13 without the second wiring line 14 therebetween, in contrast with the structure shown in FIG. 4. Although not shown, the true alignment electrode 23 can also be directly formed on the first wiring line 13 without the second wiring line 14 therebetween, similarly to the dummy columnar electrode 21b.

The semiconductor device test region according to this modification is the same as the semiconductor device test region 11a according to Embodiment 1 in other respects. Like components are provided with like reference numbers and are not described.

In the embodiments described above, the shear test is conducted on the semiconductor device formation substrate having the dummy columnar electrodes 21b on the wiring line.

However, the present invention is also applicable to a tape automated bump (TAB) in which the dummy columnar electrode 21b is directly joined onto the connection pad 3 without the wiring line 15 therebetween.

The present invention is also applicable to a case where a gold ball is joined to the connection pad. According to this method, the tip of a gold wire is heated by a capillary to form a ball part. This ball part is joined to the connection pad, and then the joining force of the ball part and the connection pad is measured by a shear test. In this case, the connection pad corresponding to the dummy columnar electrode 21b according to the present invention is formed to protrude out of the semiconductor device formation region.

Furthermore, the test to be conducted on the dummy columnar electrode is not limited to the shear test. Other tests that break down the dummy columnar electrode 21b are also applicable, such as an impact test and hardness test.

Various other modifications can be made to the semiconductor device formation substrate according to the present invention within the spirit of the invention. In short, a semiconductor device formation substrate has only to comprise a semiconductor device formation region (11, 51) including columnar electrodes (21) connected to an integrated circuit; and a semiconductor device test region (11a, 51a) for a strength test in which dummy columnar electrodes (21b) are formed and which includes a portion that protrudes out of an effective semiconductor wafer region (1a).

Moreover, a semiconductor device manufacturing method according to the present invention has only to comprise forming, on a device region including an integrated circuit and disposed in a semiconductor substrate (31), a semiconductor device formation region (11, 51) including columnar electrodes (21) connected to the integrated circuit; and forming a semiconductor device test region (11a, 51a) for a strength test including dummy columnar electrodes (21b) so that a portion of the semiconductor device test region (11a, 51a) protrudes out of an effective semiconductor wafer region (1a).

What is claimed is:

1. A semiconductor device formation substrate comprising:
a semiconductor device formation region including columnar electrodes connected to an integrated circuit; and
a semiconductor device test region for a strength test in which dummy columnar electrodes are formed and which includes a portion that protrudes out of an effective semiconductor wafer region.

2. The semiconductor device formation substrate according to claim 1, wherein the number of the dummy columnar electrodes formed in the semiconductor device test region is smaller than the number of the columnar electrodes formed in the semiconductor device formation region.

3. The semiconductor device formation substrate according to claim 2, wherein the semiconductor device test regions are provided at a plurality of places.

4. The semiconductor device formation substrate according to claim 3, wherein the outer size and cross section of the semiconductor device test region including the portion that protrudes from the semiconductor device formation substrate are the same as the outer size and cross section of the semiconductor device formation region.

5. The semiconductor device formation substrate according to claim 4, wherein the semiconductor device test region includes a dummy columnar electrode arrangement portion in which the dummy columnar electrodes are arranged in a peripheral part, and a dummy columnar electrode non-formation portion which is located closer to a central position than the dummy columnar electrode arrangement portion and in which no dummy columnar electrodes are formed.

6. The semiconductor device formation substrate according to claim 5, wherein a plurality of dummy columnar electrodes are formed in a plurality of rows the dummy columnar electrode arrangement portion of the semiconductor device test region.

7. The semiconductor device formation substrate according to claim 6, wherein the dummy columnar electrode non-formation portion of the semiconductor device test region includes an alignment electrode formation portion in which an alignment electrode is formed.

8. The semiconductor device formation substrate according to claim 7, wherein an insulating film formed on the integrated circuit and a wiring line formed on the insulating film are provided in the semiconductor device test region, and the dummy columnar electrode is formed on a land of the wiring line.

9. The semiconductor device formation substrate according to claim 8, wherein the area of the portion of the semiconductor device test region that protrudes from the effective semiconductor wafer region is 20% or less of the area of the whole semiconductor device test region.

10. A semiconductor device manufacturing method comprising:
forming, on a device region including an integrated circuit and disposed in a semiconductor substrate, a semiconductor device formation region including columnar electrodes connected to the integrated circuit; and
forming a semiconductor device test region for a strength test including dummy columnar electrodes so that a portion of the semiconductor device test region protrudes out of an effective semiconductor wafer region.

11. The semiconductor device manufacturing method according to claim 10, wherein a strength test of the dummy columnar electrode formed in the semiconductor device test region is conducted.

12. The semiconductor device manufacturing method according to claim 11, wherein the columnar electrode in each of the semiconductor device formation regions and the columnar electrode in the semiconductor device test region are formed in the same process, and
after the strength test, the periphery of the semiconductor device formation region is cut to obtain a plurality of semiconductor devices.

13. The semiconductor device manufacturing method according to claim 12, wherein the semiconductor device test regions are formed at a plurality of places on the peripheral edge of the semiconductor substrate.

14. The semiconductor device manufacturing method according to claim 13, wherein the outer size and cross section of the semiconductor device test region including the portion that protrudes from the semiconductor device formation substrate are the same as the outer size and cross section of the semiconductor device formation region.

15. The semiconductor device manufacturing method according to claim 14, wherein the semiconductor device test region includes a dummy columnar electrode arrangement portion in which the dummy columnar electrodes are arranged in a peripheral part, and a dummy columnar electrode non-formation portion which is located closer to a central position than the dummy columnar electrode arrangement portion and in which no dummy columnar electrodes are formed.

16. The semiconductor device manufacturing method according to claim 14, wherein an alignment electrode formation portion in which an alignment electrode is formed is formed adjacently to the semiconductor device test region.

17. The semiconductor device manufacturing method according to claim 16, wherein the semiconductor device test region which does not include the alignment electrode formation portion is formed adjacently to the semiconductor device test region which includes the alignment electrode formation portion.

18. The semiconductor device manufacturing method according to claim 17, wherein an insulating film formed on the integrated circuit and a wiring line stacked on the insulating film are formed in the semiconductor device formation region and the semiconductor device test region, and the dummy columnar electrode is formed on a land of the wiring line.

19. The semiconductor device manufacturing method according to claim 18, wherein the area of the portion of the semiconductor device test region that protrudes from the effective semiconductor wafer region is 20% or less of the area of the whole semiconductor device test region.

20. The semiconductor device manufacturing method according to claim 17, wherein the formation of a sealing film on the semiconductor substrate around the dummy columnar electrode and the cutting of the periphery of the semiconductor device formation region to obtain a plurality of semiconductor devices are performed when the semiconductor device test region has passed the strength test and not performed when the semiconductor device test region has failed the strength test.
